(19) United States
(12) Patent Application Publication
(10) Pub. No.: US 2024/0388154 A1
(43) Pub. Date: Nov. 21, 2024

(54) COIL SUBSTRATE, MOTOR COIL SUBSTRATE, AND MOTOR

(71) Applicant: IBIDEN CO., LTD., Ogaki (JP)

(72) Inventors: Takahisa HIRASAWA, Ogaki (JP); Takayuki FURUNO, Ogaki (JP)

(73) Assignee: IBIDEN CO., LTD., Ogaki (JP)

(21) Appl. No.: 18/786,646

(22) Filed: Jul. 29, 2024

Related U.S. Application Data
(63) Continuation of application No. PCT/JP2023/002174, filed on Jan. 25, 2023.

(30) Foreign Application Priority Data
Jan. 31, 2022 (JP) 2022-012945

(51) Int. Cl. H02K 3/26

(52) U.S. Cl. CPC H02K 3/26; H02K 2203/03

(57) ABSTRACT

A coil substrate includes a flexible substrate having a first surface and a second surface on the opposite side with respect to the first surface, and coils including first wirings and second wirings such that the first wirings are formed on the first surface of the flexible substrate and that the second wirings are formed on the second surface of the flexible substrate. The flexible substrate has one or more recesses formed on one or more longitudinal sides of the flexible substrate and is formed to be wound in a circumferential direction around an axis extending in the width direction of the flexible substrate orthogonal to the longitudinal direction of the flexible substrate such that the flexible substrate is formed into a cylindrical shape.

### CROSS-REFERENCE TO RELATED APPLICATIONS

The present application is a continuation of and claims the benefit of priority to International Application No. PCT/JP2023/002174, filed Jan. 25, 2023, which is based upon and claims the benefit of priority to Japanese Application No. 2022-012945, filed Jan. 31, 2022. The entire contents of these applications are incorporated herein by reference.

### BACKGROUND OF THE INVENTION

### 1. Field of the Invention

The present invention relates to a coil substrate, a motor coil substrate formed using the coil substrate, and a motor formed using the motor coil substrate.

### 2. Description of Background Art

International Publication No. 2018/193618 describes a coil body formed by winding a printed wiring board with spiral wiring patterns formed on both sides multiple turns into a cylindrical shape. The entire contents of this publication are incorporated herein by reference.

### SUMMARY OF THE INVENTION

According to one aspect of the present invention, a coil substrate includes a flexible substrate having a first surface and a second surface on the opposite side with respect to the first surface, and coils including first wirings and second wirings such that the first wirings are formed on the first surface of the flexible substrate and that the second wirings are formed on the second surface of the flexible substrate. The flexible substrate has one or more recesses formed on one or more longitudinal sides of the flexible substrate and is formed to be wound in a circumferential direction around an axis extending in the width direction of the flexible substrate orthogonal to the longitudinal direction of the flexible substrate such that the flexible substrate is formed into a cylindrical shape.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view schematically illustrating a coil substrate according to an embodiment of the present invention;

FIG. 2 is a cross-sectional view schematically illustrating a coil substrate according to an embodiment of the present invention;

FIG. 3 is a perspective view schematically illustrating a motor coil substrate according to an embodiment of the present invention;

FIG. 4 is an explanatory cross-sectional view schematically illustrating a portion of a motor coil substrate according to an embodiment of the present invention;

FIG. 5 is a cross-sectional view schematically illustrating a motor according to an embodiment of the present invention;

FIG. 6 is a plan view schematically illustrating a coil substrate of a first modified example according to an embodiment of the present invention;

FIG. 7 is a bottom view schematically illustrating the coil substrate of the first modified example; and

FIG. 8 is an explanatory cross-sectional view schematically illustrating a portion of the motor coil substrate of the first modified example.

### DETAILED DESCRIPTION OF THE EMBODIMENTS

Embodiments will now be described with reference to the accompanying drawings, wherein like reference numerals designate corresponding or identical elements throughout the various drawings.

### Embodiment

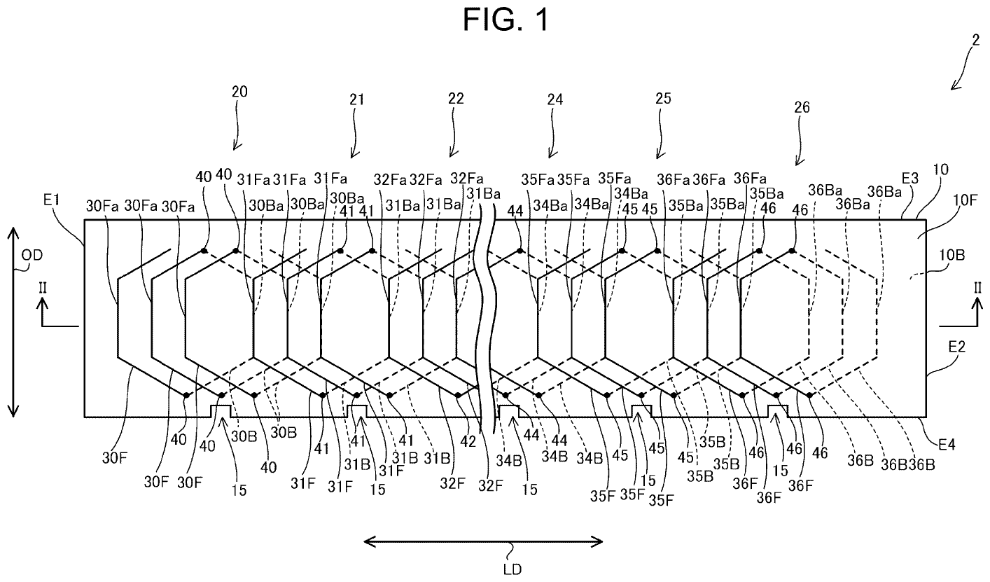

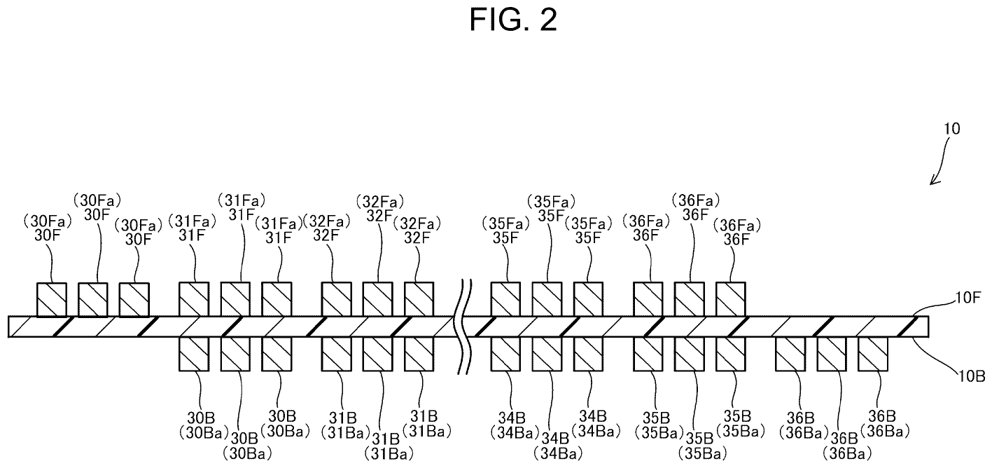

FIG. 1 is a plan view illustrating a coil substrate 2 of an embodiment. FIG. 2 is a cross-sectional view between II-II of FIG. 1. As illustrated in FIG. 1, the coil substrate 2 has a flexible substrate 10 and multiple coils (20, 21, 22, 24, 25, 26). Although FIG. 1 illustrates only the coils (20, 21, 22, 24, 25, 26), the coil substrate 2 also has coils other than the coils (20, 21, 22, 24, 25, 26).

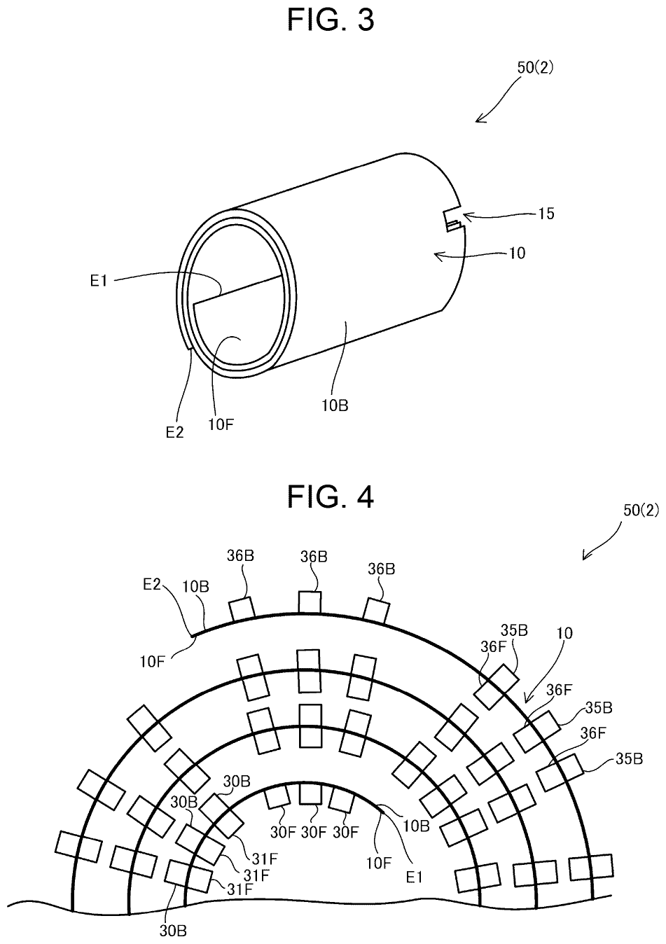

The flexible substrate 10 is a resin substrate having a first surface (10F) and a second surface (10B) on the opposite side with respect to the first surface (10F). The flexible substrate 10 is formed using an insulating resin such as polyimide or polyamide. The flexible substrate 10 is flexible. The flexible substrate 10 is formed in a rectangular shape having four sides, first side (E1)-fourth side (E4). The first side (E1) is a short side on one end side of the flexible substrate 10 in a longitudinal direction (arrow (LD) direction in FIG. 1). The second side (E2) is a short side on the other end side in the longitudinal direction. The first side (E1) and the second side (E2) are short sides extending along an orthogonal direction (arrow (OD) direction in FIG. 1) that is orthogonal to the longitudinal direction. The third side (E3) and the fourth side (E4) are long sides extending in the longitudinal direction. In FIGS. 1 and 2, illustration of a middle portion in the longitudinal direction of the flexible substrate 10 is omitted. As will be described in detail later, when the coil substrate 2 is wound into a cylindrical shape to form a motor coil substrate 50 (see FIG. 3), the first surface (10F) is positioned on an inner circumferential side and the second surface (10B) is positioned on an outer circumferential side.

Multiple recesses 15 are formed along the longitudinal direction on the fourth side (E4) of the flexible substrate 10. Each of the recesses 15 is formed by cutting a portion on the fourth side (E4) of the flexible substrate 10 in a rectangular shape. The portion cut out when forming the each of the recesses 15 may be a portion where a lead for electrolytic plating is formed when forming a coil. That is, each of the recesses 15 is formed by cutting out a portion of the flexible substrate 10 in order to remove a lead. The recesses 15 are formed on at least one of two sides in a width direction (the third side (E3) and the fourth side (E4)) of the flexible substrate 10. The recesses 15 are used for alignment when the coil substrate 2 is wound in a circumferential direction. Further, the number of turns the coil substrate is wound is not particularly limited.

The coils (20, 21, 22, 24, 25, 26) are formed to line up along the longitudinal direction of the flexible substrate 10. The coils (20, 21, 22) and the coils (24, 25, 26) may each respectively form a U phase, a V phase, and a W phase of a three-phase motor. The coils (20, 21, 22, 24, 25, 26) are formed in this order from the first side (E1) to the second side (E2). Other coils (not illustrated) are provided between the coils (20, 21, 22) and the coils (24, 25, 26). The coils are formed by first wirings (see reference numeral symbols “30F,” “31F,” and the like in FIG. 1) provided on the first surface (10F) and second wirings (see reference numeral symbols “30B,” “31B,” and the like) provided on the second surface (10B).

The coil 20 is formed by forming first wirings (30F) on the first surface (10F) side, each forming a half turn of one turn, and second wirings (30B) on the second surface (10B) side, each forming a remaining half turn, with adjacent turns being formed in a staggered manner. In FIG. 1, the coil 20 has wirings for three turns. The first wirings (30F) and second wirings (30B) forming the turns are electrically connected via via conductors 40 penetrating the flexible substrate 10. The first wirings (30F) each have a first orthogonal part (30Fa) extending along the orthogonal direction (see the arrow (OD)). The second wirings (30B) also each have a second orthogonal part (30Ba) extending along the orthogonal direction.

Similarly, the coil 21 is formed by forming first wirings (31F) on the first surface (10F) side, each forming a half turn of one turn, and second wirings (31B) on the second surface (10B) side, each forming a remaining half turn, with adjacent turns being formed in a staggered manner. The coil 21 has wirings for three turns. The first wirings (31F) and second wirings (31B) forming the turns are electrically connected via via conductors 41. The first wirings (31F) each have a first orthogonal part (31Fa) extending along the orthogonal direction (see the arrow (OD)). The second wirings (31B) also each have a second orthogonal part (31Ba) extending along the orthogonal direction.

Similarly, the coil 22 also includes first wirings (32F) and second wirings (not illustrated) for three turns. The first wirings (32F) and the second wirings are connected via via conductors 42. The first wirings (32F) each have a first orthogonal part (32Fa), and the second wirings each have a second orthogonal part.

As illustrated in FIGS. 1 and 2, the second orthogonal parts (30Ba) of the second wirings (30B) forming the coil 20 respectively overlap the first orthogonal parts (31Fa) of the first wirings (31F) forming the adjacent coil 21 with the flexible substrate 10 in between. The second orthogonal parts (31Ba) of the second wirings (31B) forming the coil 21 respectively overlap the first orthogonal parts (32Fa) of the first wirings (32F) forming the adjacent coil 22 with the flexible substrate 10 in between.

Similarly, the coil 24 also includes first wirings (not illustrated) and second wirings (34B) for three turns. The first wirings and the second wirings (34B) are connected via via conductors 44. The first wirings each have a first orthogonal part, and the second wirings (34B) each have a second orthogonal part (34Ba). The coil 25 also includes first wirings (35F) and second wirings (35B) for three turns. The first wirings (35F) and the second wirings (35B) are connected via via conductors 45. The first wirings (35F) each have a first orthogonal part (35Fa), and the second wirings (35B) each have a second orthogonal part (35Ba). The coil 26 also includes first wirings (36F) and second wirings (36B) for three turns. The first wirings (36F) and the second wirings (36B) are connected via via conductors 46. The first wirings (36F) each have a first orthogonal part (36Fa), and the second wirings (36B) each have a second orthogonal part (36Ba).

The second orthogonal parts (34Ba) of the second wirings (34B) forming the coil 24 respectively overlap the first orthogonal parts (35Fa) of the first wirings (35F) forming the adjacent coil 25 with the flexible substrate 10 in between. The second orthogonal parts (35Ba) of the second wirings (35B) forming the coil 25 respectively overlap the first orthogonal parts (36Fa) of the first wirings (36F) forming the adjacent coil 26 with the flexible substrate 10 in between.

The formation in FIGS. 1 and 2 is merely an example. In other modified examples, it is also possible that the second orthogonal parts (30Ba) of the second wirings (30B) forming the coil 20 do not respectively overlap the first orthogonal parts (31Fa) of the first wirings (31F) forming the immediately adjacent coil 21 as long as they respectively overlap the first orthogonal parts of the first wirings forming another coil (for example, the first orthogonal parts of the first wirings of a third adjacent coil). The same applies to the coils (21, 22, 24, 25, 26).

Although not illustrated, the first surface (10F), and the first wirings (30F) and the like are covered with a resin insulation layer. Similarly, the second surface (10B) and the second wirings (30B) and the like are covered with a resin insulation layer.

FIG. 3 is a perspective view schematically illustrating the motor coil substrate 50 formed using the coil substrate 2 of the embodiment (FIGS. 1 and 2). As illustrated in FIG. 3, the motor coil substrate 50 for a motor is formed by winding the coil substrate 2 of the embodiment (FIGS. 1 and 2) into a cylindrical shape. When the coil substrate 2 is wound into a cylindrical shape, the coil substrate 2 is wound N turns (where N is an integer of 2 or more) in a circumferential direction around an axis extending in the orthogonal direction (an axis extending parallel to the first side (E1)) with the first side (E1) (FIG. 1) as a starting point. In the example in FIG. 3, the coil substrate 2 is wound four turns. When the coil substrate 2 is wound into a cylindrical shape, the first surface (10F) of the flexible substrate 10 is positioned on the inner circumferential side, and the second surface (10B) is positioned on the outer circumferential side. As illustrated in FIG. 3, in the embodiment, the multiple recesses 15 formed in the flexible substrate 10 overlap each other when the flexible substrate 10 is wound in the circumferential direction.

FIG. 4 is an explanatory cross-sectional view schematically illustrating a part of the motor coil substrate 50 of FIG. 3. As illustrated in the drawing, in the motor coil substrate 50, four circumferential layers are formed by the wound flexible substrate 10. The motor coil substrate 50 has a first layer, a second layer, a third layer, and a fourth layer in order from the innermost layer. Of the flexible substrate 10, a portion near the first side (E1), which is a starting end when winding, forms the innermost first layer, and a portion near the second side (E2), which is a terminating end, forms the outermost fourth layer.

When the coil substrate 2 is wound into a cylindrical shape, the multiple recesses 15 overlap each other. As a result, the wirings formed in the M-th layer (M is an integer equal to or larger than 1 and less than N) from an inner side of the N circumferential layers that have been formed overlap the wirings formed in the (M+1)-th layer. In the example in FIG. 4, the wirings formed in the first layer overlap the wirings formed in the second layer. The wirings formed in the second layer overlap the wirings formed in the third layer. The wirings formed in the third layer overlap the wirings formed in the fourth layer. That is, the multiple recesses 15 (FIGS. 1 and 3) are used for alignment for winding the coil substrate 2 such that the wirings of the M-th layer overlap the wirings of the (M+1)-th layer. Further, the number of turns the coil substrate is wound is not particularly limited.

In the embodiment, wiring widths and inter-wiring distances and the like of the wirings forming the coils (20, 21, 22, 24, 25, 26) and the like formed in the coil substrate 2 are adjusted such that the wirings of the M-th layer overlap the wirings of the (M+1)-th layer when the coil substrate 2 is wound such that the multiple recesses 15 overlap. In the motor coil substrate 50 formed by winding the coil substrate 2 in the circumferential direction, the first surface (10F) is positioned on the inner circumferential side, and the second surface (10B) is positioned on the outer circumferential side.

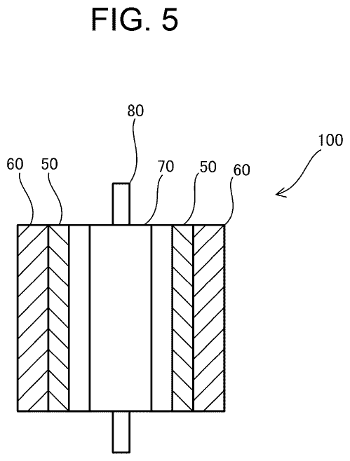

FIG. 5 is a cross-sectional view schematically illustrating a motor 100 formed using the motor coil substrate 50 of the embodiment (FIGS. 3 and 4). The motor 100 is formed by positioning the motor coil substrate 50 on an inner side of a yoke 60 and positioning a rotation shaft 80 and a magnet 70 fixed to the rotation shaft 80 on an inner side of the motor coil substrate 50.

In the above, the structures of the coil substrate 2 (FIGS. 1 and 2), the motor coil substrate 50 (FIGS. 3 and 4), and the motor 100 (FIG. 5) of the embodiment have been described. When the motor coil substrate 50 is formed using the coil substrate 2 of the embodiment, alignment is performed using the recesses 15 as a reference. Therefore, when the coil substrate 2 is wounded into a cylindrical shape, alignment between the wirings of a layer on an inner circumferential side and the wirings of a layer on an outer circumferential side is properly performed. Therefore, when the motor coil substrate 50 is formed, spatial magnetic flux distribution becomes close to a sine wave. Torque ripple is reduced. Therefore, when the motor 100 is formed using the coil substrate 2 of the embodiment, a motor 100 with stable performance can be obtained.

### ALTERNATIVE EXAMPLE

In an alternative example according to an embodiment of the present invention, the recesses 15 are formed on both the third side (E3) and the fourth side (E4) of the flexible substrate 10.

### First Modified Example

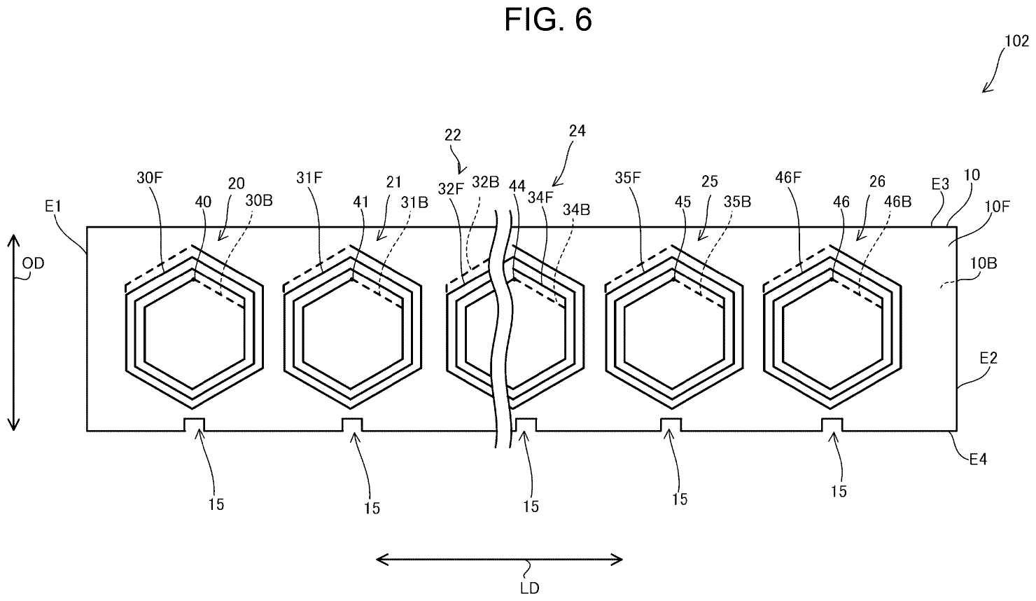

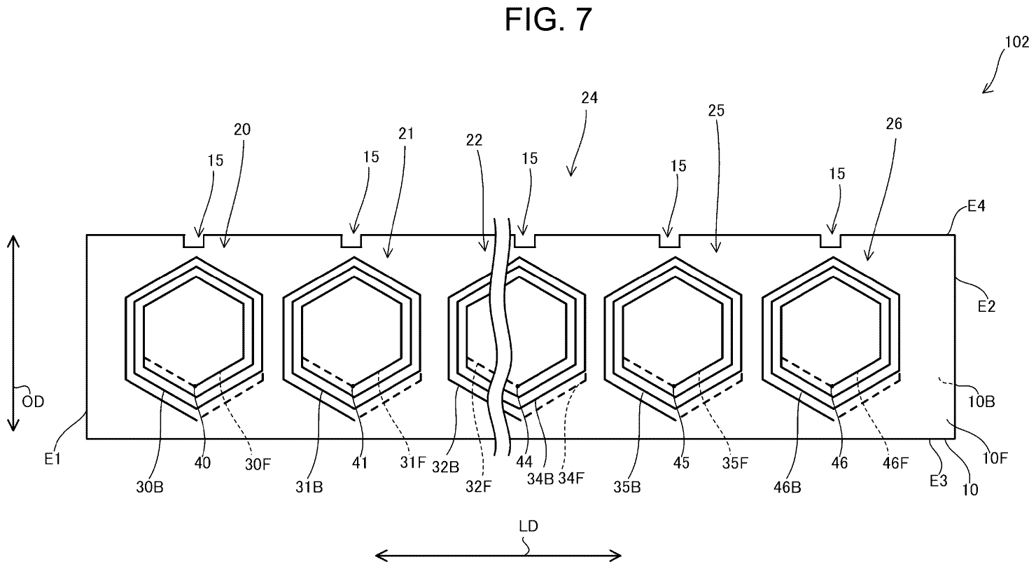

FIGS. 6-8 illustrate a first modified example according to an embodiment of the present invention. In the first modified example, the formation of the wirings forming the coils (20, 21, 22, 24, 25, 26) is different from that in the embodiment. FIG. 6 is a plan view illustrating a coil substrate 102 of the first modified example. FIG. 7 is a bottom view illustrating the coil substrate 102 of the first modified example.

The coil 20 is formed of a coil-shaped first wiring (30F) (FIG. 6) provided on the first surface (10F) and a coil-shaped second wiring (30B) (FIG. 7) provided on the second surface (10B). The first wiring (30F) and the second wiring (30B) are electrically connected via a via conductor 40 penetrating the flexible substrate 10. Similarly, the coil 21 includes a first wiring (31F), a second wiring (31B), and a via conductor 41. The coil 22 includes a first wiring (32F), a second wiring (32B), and a via conductor 42. The coil 24 includes a first wiring (34F), a second wiring (34B), and a via conductor 44. The coil 25 includes a first wiring (35F), a second wiring (35B), and a via conductor 45. The coil 26 includes a first wiring (36F), a second wiring (36B), and a via conductor 46.

As illustrated in FIG. 6, the first wiring (30F) is formed in a clockwise spiral shape (hexagonal spiral shape) from an outer circumference toward an inner circumference. The via conductor 40 is formed at an inner circumferential side end of the first wiring (30F). As illustrated in FIG. 7, the second wiring (30B) is formed in a counterclockwise spiral shape (hexagonal spiral shape) from an inner circumference toward an outer circumference. The via conductor 40 is formed at an outer circumferential side end of the second wiring (30B). The first wiring (30F) and the second wiring (30B) are formed in spiral shapes wound in the same direction when viewed from the same surface. The first wiring (30F) and the second wiring (30B) are electrically connected in series and function as one coil 20.

The first wiring (31F) (32F, 34F, 35F, 36F) and the second wiring (31B) (32B, 34B, 35B, 36B) have the same relationship as the first wiring (30F) and the second wiring (30B). The first wiring (31F) (32F, 34F, 35F, 36F) and the second wiring (31B) (32B, 34B, 35B, 36B) are electrically connected and function as one coil 21 (22, 24, 25, 26).

Also in the first modified example, the multiple recesses 15 are formed along the longitudinal direction on the fourth side (E4) of the flexible substrate 10. Further, although not illustrated, the first surface (10F) and the first wirings (30F-32F, 34F-36F) are covered with a resin insulation layer. Similarly, the second surface (10B) and the second wirings (30B-32B, 34B-36B) are covered with a resin insulation layer.

A motor coil substrate 50 (see FIG. 3) for a motor is formed by winding the coil substrate 2 of the first modified example (FIGS. 6 and 7) into a cylindrical shape. The multiple recesses 15 formed in the flexible substrate 10 overlap each other when the flexible substrate 10 is wound in the circumferential direction.

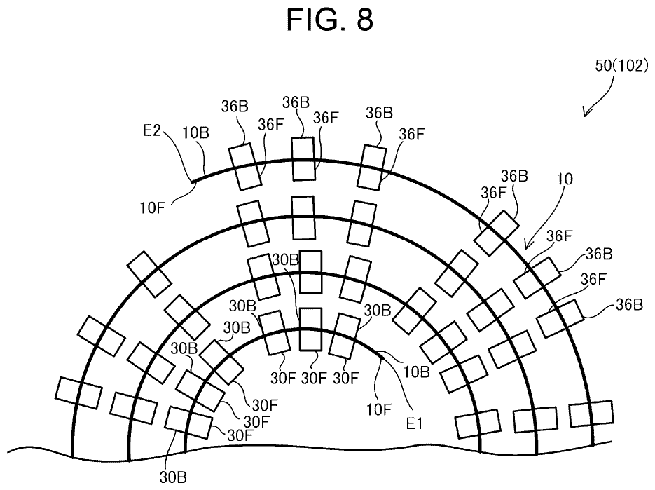

FIG. 8 is an explanatory cross-sectional view schematically illustrating a portion of the motor coil substrate 50 of the first modified example. The wirings formed in the M-th layer (M is an integer equal to or larger than 1 and less than N) from an inner side of the N circumferential layers that have been formed overlap the wirings formed in the (M+1)-th layer. The multiple recesses 15 (FIGS. 6 and 7) are used for alignment for winding the coil substrate 2 such that the wirings of the M-th layer overlap the wirings of the (M+1)-th layer.

### ALTERNATIVE EXAMPLE

In an alternative example of the first modified example, the recesses 15 are formed on both the third side (E3) and the fourth side (E4) of the flexible substrate 10.

International Publication No. 2018/193618 describes a coil body formed by winding a printed wiring board with spiral wiring patterns formed on both sides multiple turns into a cylindrical shape. Marks are provided on a printed substrate for positioning between a portion of a layer on an inner circumferential side and a portion of a layer on an outer circumferential side of the printed substrate. By overlapping a mark formed on a layer on an inner circumferential side and a mark formed on a layer on an outer circumferential side, centers of wiring patterns are aligned when the printed wiring board is wound.

In International Publication No. 2018/193618, it is thought difficult to confirm whether or not the marks are properly overlapping when a flexible substrate is wound multiple turns into a cylindrical shape. It is thought that there is a demand for a technology that allows alignment between a wiring of a layer on an inner circumferential side and a wiring of a layer on an outer circumferential side to be more properly performed when a flexible substrate is wound multiple turns into a cylindrical shape.

A coil substrate according to an embodiment of the present invention includes: a flexible substrate that has a first surface and a second surface on the opposite side with respect to the first surface; and a coil that is formed by a coil-shaped wiring provided on the first surface and a coil-shaped wiring provided on the second surface. The coil substrate can be formed into a cylindrical shape by being wound in a circumferential direction around an axis extending in a width direction orthogonal to a longitudinal direction of the flexible substrate with a reference side on one end side in the longitudinal direction as a starting point. The flexible substrate includes one or more recesses formed on at least one of two sides thereof in the width direction.

The flexible substrate of the coil substrate has the one or more recesses formed on at least one of the two sides in the width direction. Therefore, by winding the flexible substrate using the one or more recesses as a reference, when the flexible substrate is wound into a cylindrical shape, alignment between a wiring of a layer on an inner circumferential side and a wiring of a layer on an outer circumferential side can be properly performed. Therefore, when a motor coil substrate is formed by winding the coil substrate of the present invention in the circumferential direction, there is no winding misalignment, and thus, there is no coil that generates an ineffective torque. Torque ripple is reduced. Therefore, when a motor is formed using the coil substrate of the present invention, a motor with stable performance can be obtained.

In a coil substrate according to an embodiment of the present invention, the one or more recesses may be used for alignment when the coil substrate is wound in the circumferential direction.

In a coil substrate according to an embodiment of the present invention, the one or more recesses formed in the flexible substrate may be multiple recesses that are formed along a longitudinal direction on at least one side of the two sides in the width direction.

In a coil substrate according to an embodiment of the present invention, the multiple recesses may overlap each other when the flexible substrate is wound N turns (where N is an integer of 2 or more) in the circumferential direction, and when the flexible substrate is wound such that the multiple recesses overlap each other, the wiring formed in an M-th layer (M is an integer equal to or larger than 1 and less than N) from an inner side of the N circumferential layers that have been formed may overlap the wiring formed in an (M+1)-th layer.

A motor coil substrate according to an embodiment of the present invention is formed by winding the coil substrate of the present invention into a cylindrical shape. The first surface is positioned on an inner circumferential side, and the second surface is positioned on an outer circumferential side.

In a motor coil substrate according to an embodiment of the present invention, alignment between a wiring of a layer on an inner circumferential side and a wiring of a layer on an outer circumferential side can be properly performed. Therefore, there is no winding misalignment, and thus, there is no coil that generates an ineffective torque. Torque ripple is reduced. When a motor is formed using the coil substrate of the present invention, a motor with stable performance can be obtained.

A motor according to an embodiment of the present invention is formed by positioning the motor coil substrate of the present invention on an inner side of a cylindrical yoke and positioning a rotation shaft and a magnet on an inner side of the motor coil substrate.

In a motor according to an embodiment of the present invention, spatial magnetic flux distribution becomes close to a sine wave. Torque ripple is reduced. A motor with stable performance can be obtained.

Obviously, numerous modifications and variations of the present invention are possible in light of the above teachings. It is therefore to be understood that within the scope of the appended claims, the invention may be practiced otherwise than as specifically described herein.

1. A coil substrate, comprising:
a flexible substrate having a first surface and a second surface on an opposite side with respect to the first surface; and
a plurality of coils comprising a plurality of first wirings and a plurality of second wirings such that the first wirings are formed on the first surface of the flexible substrate and that the second wirings are formed on the second surface of the flexible substrate,
wherein the flexible substrate has at least one recess formed on at least one longitudinal side of the flexible substrate and is configured to be wound in a circumferential direction around an axis extending in a width direction of the flexible substrate orthogonal to a longitudinal direction of the flexible substrate such that the flexible substrate is formed into a cylindrical shape.

2. The coil substrate according to claim 1, wherein the at least one recess is positioned to align positions of the first wirings and the second wirings when the flexible substrate is wound in the circumferential direction.

3. The coil substrate according to claim 1, wherein the at least one recess formed in the flexible substrate comprises a plurality of recesses formed along the longitudinal direction of the flexible substrate.

4. The coil substrate according to claim 3, wherein the flexible substrate is formed such that the recesses overlap each other when the flexible substrate is wound N turns in the circumferential direction where N is an integer of 2 or more, and the flexible substrate is configured to be wound such that the first and second wirings have a plurality of wirings formed in an M-th layer from an inner side of N circumferential layers and a plurality of wirings formed in an (M+1)-th layer and that the wirings formed in the M-th layer overlap the wirings formed in the (M+1)-th layer, where M is an integer equal to or larger than 1 and less than N.

5. A motor coil substrate, comprising:
the coil substrate of claim 1 wound in the circumferential direction such that the first surface of the flexible substrate is positioned on an inner circumferential side of the cylindrical shape and that the second surface of the flexible substrate is positioned on an outer circumferential side of the cylindrical shape.

6. A motor, comprising:
a cylindrical yoke;
the motor coil substrate of claim 5 on an inner side of the cylindrical yoke;
a magnet on the inner side of the cylindrical yoke such that the magnet is positioned on an inner side of the motor coil substrate; and
a rotation shaft positioned on the inner side of the motor coil substrate such that the rotation shaft is positioned on an inner side of the magnet.

7. The coil substrate according to claim 2, wherein the at least one recess formed in the flexible substrate comprises a plurality of recesses formed along the longitudinal direction of the flexible substrate.

8. The coil substrate according to claim 7, wherein the flexible substrate is formed such that the recesses overlap each other when the flexible substrate is wound N turns in the circumferential direction where N is an integer of 2 or more, and the flexible substrate is configured to be wound such that the first and second wirings have a plurality of wirings formed in an M-th layer from an inner side of N circumferential layers and a plurality of wirings formed in an (M+1)-th layer and that the wirings formed in the M-th layer overlap the wirings formed in the (M+1)-th layer, where M is an integer equal to or larger than 1 and less than N.

9. A motor coil substrate, comprising:
the coil substrate of claim 2 wound in the circumferential direction such that the first surface of the flexible substrate is positioned on an inner circumferential side of the cylindrical shape and that the second surface of the flexible substrate is positioned on an outer circumferential side of the cylindrical shape.

10. A motor, comprising:
a cylindrical yoke;
the motor coil substrate of claim 9 on an inner side of the cylindrical yoke;
a magnet on the inner side of the cylindrical yoke such that the magnet is positioned on an inner side of the motor coil substrate; and
a rotation shaft positioned on the inner side of the motor coil substrate such that the rotation shaft is positioned on an inner side of the magnet.

11. A motor coil substrate, comprising:
the coil substrate of claim 3 wound in the circumferential direction such that the first surface of the flexible substrate is positioned on an inner circumferential side of the cylindrical shape and that the second surface of the flexible substrate is positioned on an outer circumferential side of the cylindrical shape.

12. A motor, comprising:
a cylindrical yoke;
the motor coil substrate of claim 11 on an inner side of the cylindrical yoke;
a magnet on the inner side of the cylindrical yoke such that the magnet is positioned on an inner side of the motor coil substrate; and
a rotation shaft positioned on the inner side of the motor coil substrate such that the rotation shaft is positioned on an inner side of the magnet.

13. A motor coil substrate, comprising:
the coil substrate of claim 4 wound in the circumferential direction such that the first surface of the flexible substrate is positioned on an inner circumferential side of the cylindrical shape and that the second surface of the flexible substrate is positioned on an outer circumferential side of the cylindrical shape.

14. A motor, comprising:
a cylindrical yoke;
the motor coil substrate of claim 13 on an inner side of the cylindrical yoke;
a magnet on the inner side of the cylindrical yoke such that the magnet is positioned on an inner side of the motor coil substrate; and
a rotation shaft positioned on the inner side of the motor coil substrate such that the rotation shaft is positioned on an inner side of the magnet.

15. The coil substrate according to claim 1, wherein the plurality of coils is formed such that each of the coils includes at least one of the first wirings and at least one of the second wirings.

16. The coil substrate according to claim 15, wherein the at least one recess is positioned to align positions of the first wirings and the second wirings when the flexible substrate is wound in the circumferential direction.

17. The coil substrate according to claim 15, wherein the at least one recess formed in the flexible substrate comprises a plurality of recesses formed along the longitudinal direction of the flexible substrate.

18. The coil substrate according to claim 17, wherein the flexible substrate is formed such that the recesses overlap each other when the flexible substrate is wound N turns in the circumferential direction where N is an integer of 2 or more, and the flexible substrate is configured to be wound such that the first and second wirings have a plurality of wirings formed in an M-th layer from an inner side of N circumferential layers and a plurality of wirings formed in an (M+1)-th layer and that the wirings formed in the M-th layer overlap the wirings formed in the (M+1)-th layer, where M is an integer equal to or larger than 1 and less than N.

19. A motor coil substrate, comprising:
the coil substrate of claim 15 wound in the circumferential direction such that the first surface of the flexible substrate is positioned on an inner circumferential side of the cylindrical shape and that the second surface of the flexible substrate is positioned on an outer circumferential side of the cylindrical shape.

20. A motor, comprising:
a cylindrical yoke;
the motor coil substrate of claim 19 on an inner side of the cylindrical yoke;
a magnet on the inner side of the cylindrical yoke such that the magnet is positioned on an inner side of the motor coil substrate; and
a rotation shaft positioned on the inner side of the motor coil substrate such that the rotation shaft is positioned on an inner side of the magnet.
